(19) United States
(12) Patent Application Publication
(10) Pub. No.: US 2013/0016034 A1
(43) Pub. Date: Jan. 17, 2013

(54) Gamma Buffer Output Compensation Circuit, Drive Circuit and Resistance Setting Method Thereof

(71) Applicants: Liangchan Liao, Shenzhen (CN); Poshen Lin, Shenzhen (CN); Nianmao Wang, Shenzhen (CN)

(72) Inventors: Liangchan Liao, Shenzhen (CN); Poshen Lin, Shenzhen (CN); Nianmao Wang, Shenzhen (CN)

(21) Appl. No.: 13/258,532

(22) PCT Filed: Aug. 9, 2011
(86) PCT No.: PCT/CN11/78146

§ 371 Date: Sep. 22, 2011

(30) Foreign Application Priority Data
Jul. 12, 2011 (CN) 201110194531.5

(51) Int. Cl. G09G 3/36; H03K 3/00

(52) U.S. Cl. 345/92; 327/108

(57) ABSTRACT

The present invention discloses a gamma buffer output compensation circuit, a drive circuit and a resistance setting method thereof. The gamma buffer output compensation circuit comprises a set of variable compensating resistor modules which are respectively connected to each output terminal of the gamma buffer and have regulable resistance. The present invention uses the method of setting variable compensating resistor modules with regulable resistance in front of each output terminal of the gamma buffer to replace the existing compensating resistors with fixed resistance. The resistance of the compensating resistors in front of each output terminal can be regulated through external operation so that the same compensation circuit can be applied to different types of machines. Therefore, the gamma buffer output compensation circuit can be directly developed in advance without regard to the difference of different types of machines, and the resistance of suitable compensating resistors can be regulated in later period. Thus, the generality of gamma buffers is increased, and the development cycle of machines is reduced.

### TECHNICAL FIELD

The present invention relates to the technical field of LCD panels, particularly to a gamma buffer output compensation circuit, a liquid crystal display (LCD) panel drive circuit and a resistance setting method thereof.

### BACKGROUND

The functional structure of the frequently used programmable gamma buffers at present is shown in FIG. 1. The external I2C bus controller of the programmable gamma buffer writes the code value corresponding to the gamma voltage to be output into the internal register through the internal I2C bus controller and the read/write controller for reading/writing internal register and memory, and the gamma voltage is output by the drive of the buffer through the digital to analogue converter (DAC). In order to maintain the stability of the output and ensure the response of the corresponding frequency, it is necessary to add resistor-capacitor to the output terminal of the programmable gamma buffer for compensation. The loadings of TFT-LCD modules of different sizes are different, and the resistances of the compensating resistors required by the programmable gamma buffer are different. Therefore, for different machines, it is necessary to find appropriate resistance of compensating resistors through many experiments. Then, the overall circuit design is accomplished in accordance with the obtained resistance of compensating resistors, and the overall machine is manufactured in accordance with the determined circuit, and this results in a longer cycle for the overall development process.

### SUMMARY

The aim of the present invention is to provide a gamma buffer output compensation circuit, a LCD panel drive circuit and a resistance setting method thereof with the advantages of better generality and a shorter development cycle.

The purpose of the present invention is achieved by the following technical schemes.

A gamma buffer output compensation circuit, wherein the gamma buffer output compensation circuit comprises a set of variable compensating resistor modules which are respectively connected to each output terminal of the gamma buffer and have regulable resistance.

The variable compensating resistor modules comprises a set of variable compensating resistors which are respectively in series connection between the gamma buffer and each output terminal, and a variable resistor controller which is in controllable connection with the variable compensating resistors and is used for regulating the resistance of the variable compensating resistors.

The variable compensating resistors connected to each output terminal can be one or several variable resistors with digital controller in series connection, and the variable resistor controller can be a set of switch units which are in controllable connection with each variable resistor with digital controller. The operation of regulating and controlling the resistance becomes simpler by using the digital control method.

The gamma buffer comprises an internal register and an internal memory, the internal register is respectively in digital controllable connection with each switch unit of the variable compensating resistor modules; the internal register outputs digital signals in accordance with its input digit code values of the resistance of the compensating resistors to control the opening or closing of the corresponding switch unit; and the internal memory stores the digit code values of the resistance of the compensating resistors. Such design makes it more convenient and faster to regulate the resistance of the compensating resistors of the variable compensating resistor modules by programming through the digital control.

A LCD panel drive circuit comprises a gamma buffer and a gamma buffer output compensation circuit set at the output terminal of the gamma buffer, wherein the gamma buffer output compensation circuit comprises a set of variable compensating resistor modules which are respectively connected to each output terminal of the gamma buffer and have regulable resistance.

The variable compensating resistor modules comprises a set of variable compensating resistors which are respectively in series connection between the gamma buffer and each output terminal, and a variable resistor controller which is in controllable connection with the variable compensating resistors and is used for regulating the resistance of the variable compensating resistors.

The variable compensating resistors connected to each output terminal can be one or several variable resistors with digital controller in series connection, and the variable resistor controller can be a set of switch units which are in controllable connection with each variable resistor with digital controller. The operation of regulating and controlling the resistance becomes simpler by using the digital control method.

The gamma buffer comprises an internal register and an internal memory, the internal register is respectively in digital controllable connection with each switch unit of the variable compensating resistor modules; the internal register outputs digital signals in accordance with its input digit code values of the resistance of the compensating resistors to control the opening or closing of the corresponding switch unit; and the internal memory stores the digit code values of the resistance of the compensating resistors. Such design makes it more convenient and faster to regulate the resistance of the compensating resistors of the variable compensating resistor modules by programming through the digital control.

A resistance setting method for the gamma buffer compensation circuit, comprises the following steps:

S1: Obtaining the resistance of the compensation circuit required by the corresponding LCD panel;

S2: Regulating the resistance of the compensating resistors which are connected to each output of the gamma buffer and have regulable resistance;

S3: Monitoring the overall circuit; if qualified, complete the setting; if not qualified, repeat the step S2 to regulate the resistance.

The variable compensating resistor modules of the gamma buffer output compensation circuit comprise one or several variable resistors with digital control in series connection between the gamma buffer and each output terminal, and a set of switch units which are in controllable connection with each variable resistor with digital controller; the gamma buffer comprises an internal register and an internal memory, the internal register is respectively in digital controllable connection with each switch unit of the variable compensating resistor modules.

In the step S2, the digit code values of the resistance of the compensating resistors are written into the internal register by programming; the internal register outputs digital signals in accordance with its input digit code values of the resistance of the compensating resistors to control the opening or closing of the corresponding switch unit, and the corresponding variable resistor with digital controller is selected to set the variable compensating resistor.

In the step S3, after the overall circuit is monitored for qualification, do the following step to complete the setting.

S4: Writing the digit code values of the resistance of the compensating resistors into the memory.

To replace the existing compensating resistors with fixed resistance, the present invention uses the method of setting variable compensating resistor modules with regulable resistance in front of each output terminal of the gamma buffer. The resistance of the compensating resistors in front of each output terminal can be regulated through external operation so that the same compensation circuit can be applied to different types of machines. Therefore, the gamma buffer output compensation circuit can be directly developed in advance without consideration of the differences of different types of machines, and the resistance of the compensating resistors can be regulated to a suitable value in later period. Thus, the generality of gamma buffers is increased, and the development cycle of machines is reduced. Furthermore, with this design, the overall corresponding circuit can be used even when other compensating resistors need to be regulated in later period, in which case only the resistance of the compensating resistors need to be regulated again; this design provides the possibility of flexible regulation in later period.

### BRIEF DESCRIPTION OF FIGURES

FIG. 1 is the schematic diagram of the gamma buffer output compensation circuit in the prior art.

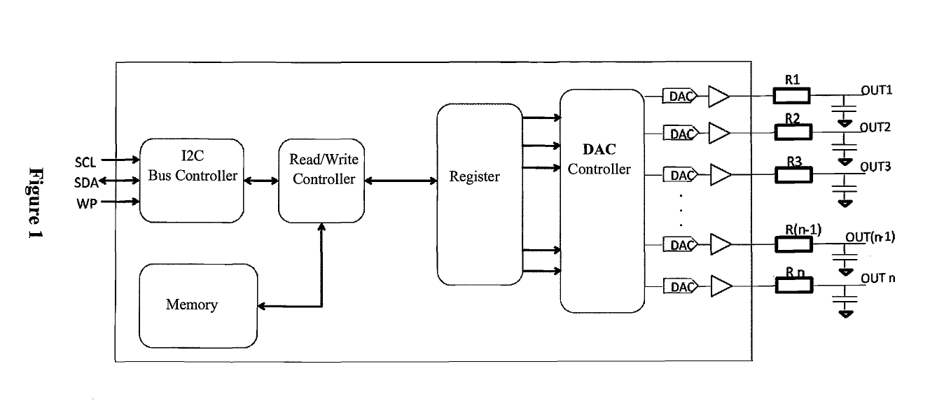

FIG. 2 is the schematic diagram of the gamma buffer output compensation circuit of one embodiment of the present invention.

FIG. 3 is the specific schematic diagram of the variable compensating resistor module of the gamma buffer output compensation circuit of one embodiment of the present invention.

### DETAILED DESCRIPTION

The present invention will further be described in accordance with the figures and the preferred embodiments as follows.

The invention proposes a scheme for regulating the resistance of the compensating resistors according to the different TFT-LCD Module loading. The gamma buffer output compensation circuit of one embodiment of the present invention comprises a set of variable compensating resistor modules which are respectively connected to each output terminal of the gamma buffer and have regulable resistance. The overall structure of the gamma buffer output compensation circuit is generally the same as that of the existing gamma buffer output compensation circuit, except that the present invention uses the variable compensating resistors with regulable resistance to replace the existing compensating resistors with fixed resistance. The resistance of the compensating resistors in front of each output terminal can be regulated through external operation so that the same compensation circuit can be applied in different types of machines. Therefore, the gamma buffer output compensation circuit can be directly developed in advance without consideration of the difference of the different types of machines, and the resistance of suitable compensating resistors can be regulated in later period. Thus, the generality of gamma buffers is increased, and the development cycle of machines is reduced. Furthermore, with this design, the overall corresponding circuit can be used even when other compensating resistors need to be regulated in later period, in which case only the resistance of the compensating resistors need to be regulated again; this design provides the possibility of flexible regulation in later period.

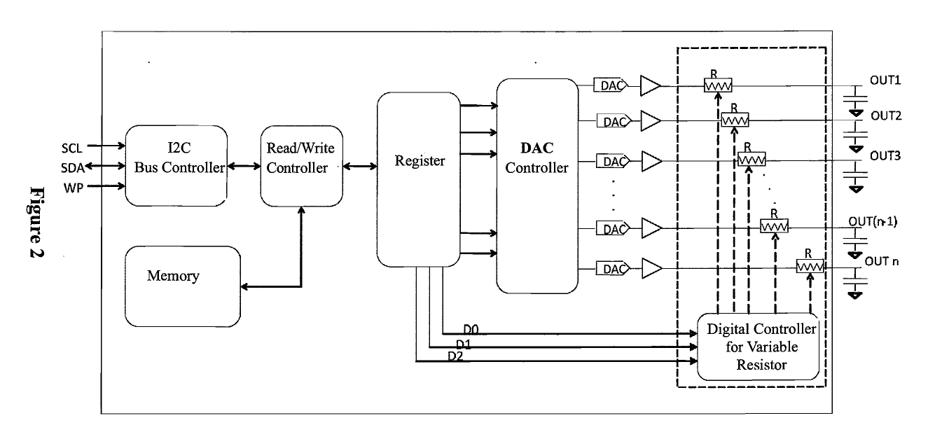

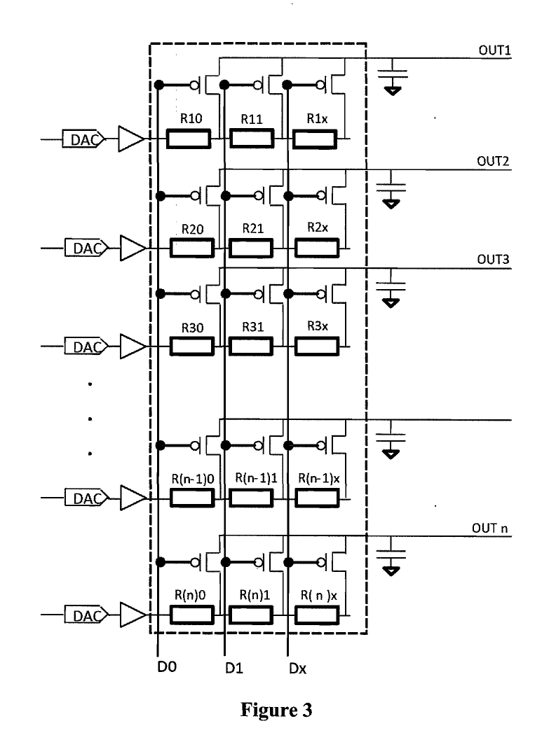

The variable compensating resistor modules comprise one or several variable compensating resistors respectively in series connection between the gamma buffer and each output terminal, and a variable resistor controller which is in controllable connection with the variable compensating resistor and is used for regulating the resistance of the variable compensating resistors.

Wherein, the variable resistor controller can be controlled by digital signals to obtain ideal resistance of the compensating resistors, as shown in FIGS. 2 and 3; the variable compensating resistors connected to each output terminal can be a set of variable resistors with digital controllers in series connection mutually, and the variable resistor controller can be a set of NMOS switch units array connected with each variable resistor with digital controller by controller; the gamma buffer comprises an internal register and an internal memory, wherein the internal register is respectively in digital controllable connection with each switch unit of the variable compensating resistor modules; the internal register outputs digital signals in accordance with its input digit code values of the resistance of the compensating resistors to control the opening or closing of the corresponding switch unit in the NMOS switch unit array, and selects corresponding variable resistor with digital controller. The internal memory stores the digit code values of the gamma voltage and the digit code values of the resistance of the compensating resistors. The present invention will further be described in accordance with FIG. 3 and the following Table 1.

TABLE 1

| | D0 | D1 | . . . | Dx | R |
|---|---|---|---|---|---|
| A | 0 | 0 | . . . | 1 | R(n)0 + R(n)1 + . . . + R(n)x |
| . . . | . . . | . . . | . . . | . . . | . . . |
| B | 0 | 1 | . . . | 0 | R(n)0 + R(n)1 |
| C | 1 | 0 | . . . | 0 | R(n)0 |

Take the embodiment of only the digital signals D0, D1 and D2 as an example. The digital signals D0, D1 and D2 output by the internal register respectively controls NMOS switch unit array to select the required resistance of the compensating resistors. There may be three conditions A, B and C; the digit code values of the resistance of the compensating resistors corresponding to D0, D1 and D2 are respectively 001, 010 and 100; and the corresponding resistance of the compensating resistors are R(n)0+R(n)1+R(n)2, R(n)0+R(n)1 and R(n)0. Such design makes it more convenient and faster to regulate the resistance of the compensating resistors of the variable compensating resistor modules by programming through the digital controller.

There can be more digital signal channels, for example, the digit code values of the resistance of the compensating resistors corresponding to D0, D1, . . . DX are 00 . . . 1, 01 . . . 0, . . . , 10 . . . 0, and corresponding resistance of the compensating resistors are R(n)0+R(n)1+ . . . +R(n) X, R(n)0+R(n)1, R(n)0, [n can range from 1, 2, 3, . . . (n−1) to n]. Generally speaking, there may be 14 channels of output circuits in one gamma buffer, i.e. the maximum value of N in the above formula can be 14; while resistance on each channel can be added, namely more X can be set as required, but the square matrix circuit formed by switch tubes will be large in this case.

After the above compensation circuit of the gamma buffer is achieved, the resistance of the compensating resistors will be set through the following steps.

S1: Obtaining the resistance of the compensation circuit required by the corresponding LCD panel.

S2: Regulating the resistance of the variable compensating resistors connected to each output terminal of the gamma buffer: for example, the digit code values of the resistance of the compensating resistors are written into the internal register by programming; the internal register outputs digital signals in accordance with its input digit code values of the resistance of the compensating resistors to control the opening or closing of the corresponding switch unit; and corresponding variable resistor with digital controller is selected to set the variable compensating resistor.

S3: Monitoring the overall circuit; if qualified, write the digit code values of the resistance of the compensating resistors into the memory, complete the setting; if not qualified, repeat step S2 to regulate the resistance.

After the resistance of the compensating resistors is set, do the following steps when the power source is turned on every time: the internal register reads the digit code value of the resistance of the compensating resistors from the internal memory; outputs digital signals in accordance with its read digit code value of the resistance of the compensating resistors to control the opening or closing of the corresponding switch unit; selects the corresponding variable resistor with digital controller; and regulates the resistance of the compensating resistors to be automatically restored after the power source is turned on every time.

The present invention is described in detail in accordance with the above contents with the specific preferred embodiments. However, this invention is not limited to the specific embodiments. For example, the above embodiment can use the digital control mode to regulate the resistance of the variable compensating resistor modules, and can use other schemes, and even can use the ordinary variable resistor so long as the mode can be used to regulate the resistance of the variable compensating resistors of the gamma buffer. For the ordinary technical personnel of the technical field of the present invention, on the premise of keeping the conception of the present invention, the technical personnel can also make simple deductions or replacements, and all of which should be considered to belong to the protection scope of the present invention.

We claim:

1. A gamma buffer output compensation circuit, comprising: a set of variable compensating resistor modules which are respectively connected to each output terminal of the gamma buffer and have regulable resistance.

2. A gamma buffer output compensation circuit of claim 1, wherein said variable compensating resistor modules comprise a set of variable compensating resistors respectively in series connection between the gamma buffer and each output terminal, and a variable resistor controller which is in controllable connection with the variable compensating resistors and is used for regulating the resistance of the variable compensating resistors.

3. A gamma buffer output compensation circuit of claim 2, wherein said variable compensating resistors connected to each output terminal can be one or several variable resistor with digital controller in series connection, and said variable resistor controller can be a set of switch units which are in controllable connection with each variable resistor with digital controller.

4. A gamma buffer output compensation circuit of claim 3, wherein said gamma buffer comprises an internal register and an internal memory, wherein the internal register is respectively in digital controllable connection with each switch unit of the variable compensating resistor modules; the internal register outputs digital signals in accordance with its input digit code values of the resistance of the compensating resistors to control the opening or closing of the corresponding switch unit; and said internal memory stores the digit code values of the resistance of the compensating resistors.

5. A liquid crystal display (LCD) panel drive circuit, comprising: a gamma buffer, and a gamma buffer output compensation circuit set at the output terminal of the gamma buffer; said gamma buffer output compensation circuit comprises a set of variable compensating resistor modules which are respectively connected to each output terminal of the gamma buffer and have regulable resistance.

6. A LCD panel drive circuit of claim 5, wherein said variable compensating resistor modules comprise a set of variable compensating resistors respectively in series connection between the gamma buffer and each output terminal, and a variable resistor controller which is in controllable connection with the variable compensating resistors and is used for regulating the resistance of the variable compensating resistors.

7. A LCD panel drive circuit of claim 6, wherein said variable compensating resistors connected to each output terminal can be one or several variable resistor with digital controller in series connection, and said variable resistor controller can be a set of switch units which are in controllable connection with each variable resistor with digital controller.

8. A LCD panel drive circuit of claim 7, wherein said gamma buffer comprises an internal register and an internal memory, said internal register is respectively in digital controllable connection with each switch unit of the variable compensating resistor modules; the internal register outputs digital signals in accordance with its input digit code values of the resistance of the compensating resistors to control the opening or closing of the corresponding switch unit; and said internal memory stores the digit code values of the resistance of the compensating resistors.

9. A resistance setting method for said gamma buffer compensation circuit of claim 1, comprising the steps of:
S1: obtaining the resistance of the compensation circuit required by the corresponding LCD panel;
S2: regulating the resistance of the compensating resistors which are connected to each output terminal of the gamma buffer and have regulable resistance;
S3: monitoring the circuits of the overall machine; if qualified, complete the setting; if not qualified, repeat the step S2 to regulate the resistance.

10. A resistance setting method for said gamma buffer compensation circuit of claim 9, wherein said variable compensating resistor modules of the gamma buffer output compensation circuit comprise one or several variable resistors with digital controller in series connection between the gamma buffer and each output terminal, and a set of switch units connected with each variable resistor with digital controller by controller; said gamma buffer comprises an internal register and an internal memory, the internal register is respectively in digital controllable connection with each switch unit of the variable compensating resistor modules;
In said step S2, the digit code values of the resistance of the compensating resistors are written into the internal register by programming; the internal register outputs digital signals in accordance with its input digit code values of the resistance of the compensating resistors to control the opening or closing of the corresponding switch unit, and the corresponding variable resistor with digital controller is selected to set the regulable compensating resistor;
In said step S3, after the overall circuit is monitored for qualification, do the following step to accomplish setting;
S4: writing the digit code values of the resistance of the compensating resistors into the memory.
